(19) United States
(12) Patent Application Publication
(10) Pub. No.: US 2012/0181560 A1
(43) Pub. Date: Jul. 19, 2012

(54) LED WIRING BOARD, LIGHT EMITTING MODULE, METHOD FOR MANUFACTURING LED WIRING BOARD AND METHOD FOR MANUFACTURING LIGHT EMITTING MODULE

(75) Inventors: Yasuji HIRAMATSU, Gifu (JP); Yoshiyuki Ido, Gifu (JP); Wataru Furuichi, Gifu (JP)

(73) Assignee: IBIDEN CO., LTD., Ogaki-shi (JP)

(21) Appl. No.: 13/349,599

(22) Filed: Jan. 13, 2012

(30) Foreign Application Priority Data
Jan. 17, 2011 (JP) 2011-007361

(51) Int. Cl. H01L 33/60; H05K 3/10; H05K 1/02; H01L 33/48; H05K 1/00

(52) U.S. Cl. 257/98; 438/27; 174/250; 174/256; 174/258; 427/98.4; 257/E33.072

(57) ABSTRACT

An LED wiring board includes an insulator layer, a conductor layer (a wiring pattern layer) formed on the insulator layer, and a white reflective film which is formed on the insulator layer and which includes a white colorant and a binder thereof. The conductor layer includes a first wiring pattern and a second wiring pattern, and the white reflective film has a portion which is between the first wiring pattern and the second wiring pattern and which is thinner than both of the first wiring pattern and the second wiring pattern.

### CROSS-REFERENCE TO RELATED APPLICATION

This application claims the benefit of Japanese Patent Application No. 2011-7361, filed on Jan. 17, 2011, the entire disclosure of which is incorporated by reference herein.

### FIELD

This application relates generally to an LED (light emitting diode) wiring board, a light emitting module, a method for manufacturing the LED wiring board and a method for manufacturing the light emitting module.

### BACKGROUND

Unexamined Japanese Patent Application KOKAI Publication No. 2009-130234 discloses an LED wiring board including an insulator layer, a conductor pattern (a circuit foil) and a white reflective film (a solder resist) both formed on the insulator layer.

The disclosure of Unexamined Japanese Patent Application KOKAI Publication No. 2009-130234 is herein incorporated by reference in this specification.

### SUMMARY

An LED wiring board according to the invention includes: an insulator layer; a wiring pattern layer formed on the insulator layer; and a white reflective film which is formed on the insulator layer and which comprises a white colorant and a binder thereof, the wiring pattern layer comprising a first wiring pattern and a second wiring pattern, and the white reflective film including a portion which is between the first wiring pattern and the second wiring pattern and which is thinner than both of the first wiring pattern and the second wiring pattern.

A light emitting module of the invention includes: the above-explained LED wiring board; and an LED device.

A method for manufacturing an LED wiring board according to the invention includes: forming a wiring pattern and a white reflective film on an insulator layer, the white reflective film comprising a white colorant and a binder thereof; and polishing a surface of the white reflective film to make the white reflective film thinner than the wiring pattern.

A method for manufacturing a light emitting module according to the invention includes, mounting an LED device on the LED wiring board manufactured by the above-explained method.

### BRIEF DESCRIPTION OF THE DRAWINGS

A more complete understanding of this application can be obtained when the following detailed description is considered in conjunction with the following drawings, in which:

FIG. 1 is a cross-sectional view showing an LED wiring board according to an embodiment of the present invention;

FIG. 2 is a cross-sectional view showing a light emitting module according to the embodiment of the present invention;

FIG. 3 is a plan view showing a shape of a wiring pattern layer (a first wiring pattern and a second wiring pattern) of the LED wiring board according to the embodiment of the present invention;

FIG. 4 is a diagram for explaining a relationship between a thickness of a white reflective film and that of the wiring pattern layer (the first wiring pattern and the second wiring pattern) in the LED wiring board according to the embodiment of the present invention;

FIG. 5 is a diagram for explaining an operation of the light emitting module according to the embodiment of the present invention;

FIG. 6 is a graph showing a reflectance of light in a predetermined wavelength range for each white reflective film formed of a different material in the LED wiring board according to the embodiment of the present invention;

FIG. 7 is a table showing the detail of each sample according to examples 1-1 to 1-4 and reference examples 1-1 and 1-2;

FIG. 8A is a graph showing a reflectance of light in a predetermined wavelength range for a white reflective film formed of an anatase titanium dioxide and a white reflective film formed of a rutile titanium dioxide in the LED wiring board according to the embodiment of the present invention;

FIG. 8B is a graph showing a reflectance of light in a predetermined wavelength range for a white reflective film formed of rutile titanium dioxide and a silicon resin and a white reflective film formed of zirconia and a silicon resin in the LED wiring board according to the embodiment of the present invention;

FIG. 9 is a table showing the detail of each sample according to examples 2-1 to 2-4;

FIG. 10 is a graph showing a time-dependent change in a reflectance of light with a predetermined wavelength for each white reflective film formed of a different material in the LED wiring board according to the embodiment of the present invention;

FIG. 11 is a table showing the detail of each sample according to examples 3-1 to 3-4, a comparative example 3-1 and a reference example 3-1;

FIG. 12 is a flowchart showing a method for manufacturing the LED wiring board according to the embodiment of the present invention;

FIG. 13 is a diagram for explaining a process of preparing an insulating substrate in the manufacturing method shown in FIG. 12;

FIG. 14A is a diagram for explaining a process of forming a through-hole in the insulating substrate in the manufacturing method shown in FIG. 12;

FIG. 14B is a diagram for explaining a process of forming a non-through-hole in the insulating substrate according to a modified example of the manufacturing method shown in FIG. 12;

FIG. 15 is a diagram for explaining a plating process in the manufacturing method shown in FIG. 12;

FIG. 16 is a diagram for explaining a process of forming an etching resist in the manufacturing method shown in FIG. 12;

FIG. 17 is a diagram for explaining a process of etching a conductor layer in the manufacturing method shown in FIG. 12;

FIG. 18 is a diagram for explaining a first process of forming a white reflective film in the manufacturing method shown in FIG. 12;

FIG. 19 is a diagram for explaining a second process following the first process in FIG. 18;

FIG. 20A is a cross-sectional view showing an example having the corrosion resistant film of the wiring pattern layer (the first wiring pattern and the second wiring pattern) omitted in the LED wiring board according to the embodiment of the present invention;

FIG. 20B is a diagram for explaining a modified example relating to a dimension of a white reflective film in the LED wiring board according to the embodiment of the present invention;

FIG. 21 is a plan view showing another shape of the wiring pattern layer (the first wiring pattern and the second wiring pattern) according to the embodiment of the present invention;

FIG. 22 is a cross-sectional view showing a modified example of an insulator layer according to another embodiment of the present invention;

FIG. 23 is a diagram showing another example having LED devices mounted in a different scheme in the light emitting module according to the embodiment of the present invention;

FIG. 24A is a plan view showing an LED wiring board according to the other embodiment of the present invention;

FIG. 24B is a partial cross-sectional view of the LED wiring board shown in FIG. 24A;

FIG. 25A is a diagram for explaining a first process of forming a wiring pattern layer (a first wiring pattern and a second wiring pattern) according to the yet other embodiment of the present invention;

FIG. 25B is a diagram for explaining a second process following the first process in FIG. 25A; and

FIG. 25C is a diagram for explaining a third process following the second process in FIG. 25B.

### DETAILED DESCRIPTION

Embodiments of the present invention will be explained in detail with reference to the accompanying drawings. Arrows Z1 and Z2 in the drawings indicate thickness directions of a wiring board corresponding to the normal line directions of a principal surface (a front face or a rear face) of the wiring board, respectively. Conversely, arrows X1, X2, Y1 and Y2 indicate sides of the wiring board orthogonal to a Z direction, respectively. Hence, the principal surface of the wiring board is an X-Y plane, while the side face of the wiring board is an X-Z plane or a Y-Z plane.

The two principal surfaces of the wiring board directed in opposite normal line directions are referred to as a first plane (a surface at the Z1 side) and a second plane (a surface at the Z2 side). In this specification, an expression “right below” indicates the Z direction (toward Z1 or Z2), and a plane means the X-Y plane if not particularly pointed out.

A conductor layer includes one or a plurality of conductor patterns. The conductor layer may include a conductor pattern configuring an electronic circuit, such as a wiring (including a ground wire), a pad, or a land, or may include a planar conductor pattern (a plane pattern) that does not configure an electronic circuit.

An aperture includes an opening, a groove, a notch, and a cut line, etc. An opening is not limited to a through-hole, and the term opening is defined as to include a non-through-hole. A conductor formed in a through-hole is referred to as a through-hole conductor.

Plating includes wet plating like electrolytic plating, and dry plating, such as PVD (Physical Vapor Deposition) and CVD (Chemical Vapor Deposition).

Light is not limited to visible light. Light includes, in addition to visible light, ultraviolet rays, electromagnetic waves with a short wavelength like X rays, and electromagnetic waves with a long wavelength like infrared rays.

According to the conventional LED wiring board disclosed in Unexamined Japanese Patent Application KOKAI Publication No. 2009-130234, the white reflective film is thicker than the conductor pattern, which disturbs disposing of the white reflective film right below the LED devices. Hence, in the case of the LED wiring board having a substrate formed of a resin material, the resin changes the properties due to light emitted by the LED devices, resulting in a concern for the deterioration of the performance of the LED wiring board. Deterioration of the resin forming the substrate is greatly concerned in, in particular, a portion disposed right below and near the LED devices.

The present invention has been made in view of such a circumstance, and it is an object of the present invention to enhance the durability of an LED wiring board and to improve the reflective performance thereof. Moreover, it is another object to maintain a high performance even if the LED wiring board is formed by a resin substrate.

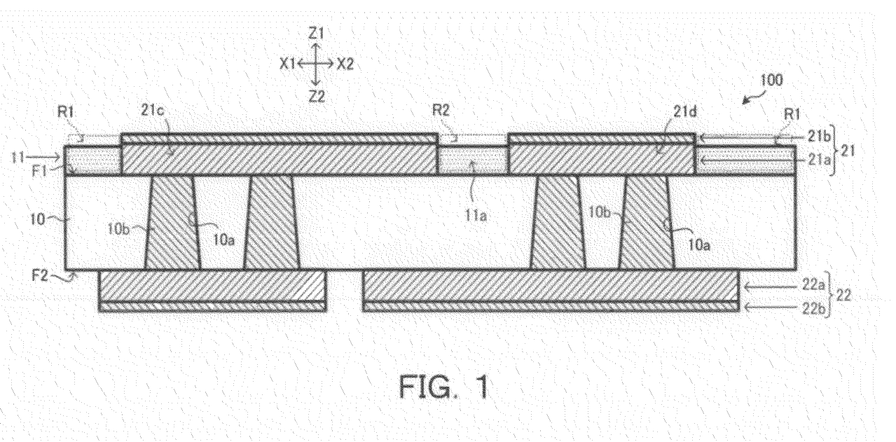

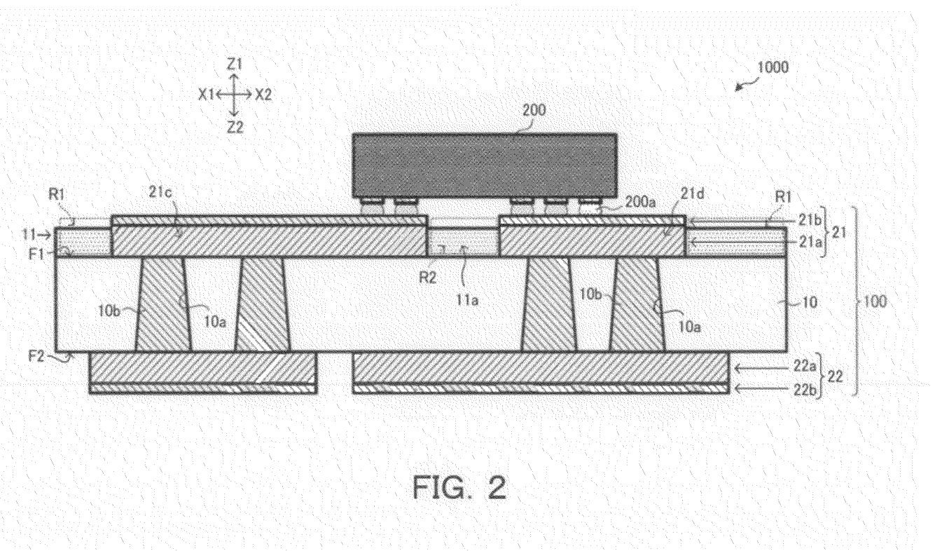

FIG. 1 shows a general configuration of an LED wiring board 100 according to an embodiment. As shown in FIG. 2, the LED wiring board 100 shown in FIG. 1 and built with an LED device 200 configures a light emitting module 1000.

As shown in FIG. 1, the LED wiring board 100 includes a substrate (an insulating layer) 10, a white reflective film 11, a conductor layer 21 (including a conductor pattern 21a, and a corrosion resistant film 21b), and a conductor layer 22 (including a conductor pattern 22a, and a corrosion resistant film 22b). In the following explanation, one of the front and rear faces (the two principal surfaces) of the substrate 10 is referred to as a first plane F1, and the other is referred to as a second plane F2. The LED device 200 is mounted on the first plane F1 of the substrate 10 in this embodiment (see FIG. 2).

The substrate 10 of this embodiment is, for example, a rectangular substrate with an insulation property. It is preferable that the substrate 10 should be a resin substrate, and a specific example of such is a glass cloth (a reinforcement material) containing an epoxy resin (hereinafter, referred to as a glass-epoxy). The epoxy resin is thermosetting. A preferable resin forming the substrate 10 is a thermosetting resin. The reinforcement material has a smaller thermal expansion coefficient than that of the main material (the epoxy resin in this embodiment). The substrate 10 containing the reinforcement material can reduce the thermal expansion coefficient, and thus a warpage of the substrate 10 is suppressed. Moreover, the substrate 10 containing the reinforcement material makes the thermal expansion coefficient thereof closer to the thermal expansion coefficient of the LED device 200, thereby improving the reliability of the substrate 10. This is because the LED device 200 is formed of a non-organic material, and the thermal expansion coefficient thereof is smaller than the resin material. In order to suppress a warpage of the wiring board 100, it is preferable to make the thermal expansion coefficient of the substrate 10 closer to (desirably, identical to) the thermal expansion coefficient of the white reflective film 11.

A preferable reinforcement material is a non-organic material, such as a glass fiber (e.g., a glass cloth or a glass nonwoven cloth), an aramid fiber (e.g., an aramid nonwoven cloth), or a silica filler. The reinforcement material is not limited to those examples, and a reinforcement material formed of an organic material, such as paper, PET (polyethylene terephthalate), or polyimide, can be used. Instead of the epoxy resin, a polyester resin, a bismaleimide-triazine resin (a BT resin), an imide resin (polyimide), a phenol resin or an allylation phenylene ether resin (an A-PPE resin) can be used.

According to this embodiment, the substrate (an insulating layer) 10 is formed of a resin substrate. The base material formed of a resin is not likely to be cracked due to the high flexibility, and thus the substrate 10 can be easily thinned in comparison with a ceramic substrate formed of alumina or AlN (aluminum nitride), etc. As an example, when the substrate 10 is a ceramic substrate, it is difficult to reduce the thickness of the substrate 10 to be equal to or smaller than substantially 0.5 mm since such a substrate is easily cracked. Conversely, the resin substrate is flexile, and the thickness of the substrate 10 that is a resin substrate can be substantially 0.10 mm. Moreover, in comparison with the ceramic substrate, the resin substrate can be obtained at a low cost, and is easy to process like boring.

The substrate 10 is formed with through-holes 10a that pass all the way through the substrate 10. Plating of, for example, copper is filled in each through-hole 10a, and thus a through-hole conductor (a filled conductor) 10b is formed. In this embodiment, the through-hole conductor 10b is formed of copper plating. The through-hole conductor 10b has a shape that is a tapered cylinder (conical trapezoid) with a diameter being reduced toward the LED mounting surface side (the first plane: Z1 side). The present invention is not limited to such a shape, and the material and shape of the through-hole conductor 10b are optional such that the through-hole conductor 10b has a shape that is a tapered cylinder (conical trapezoid) with a reduced diameter toward the rear side (the second plane: Z2 side) of the LED mounting surface, or a tapered shape with a narrow center in such a way that the diameter is reduced toward the center from the first plane side and the second plane side.

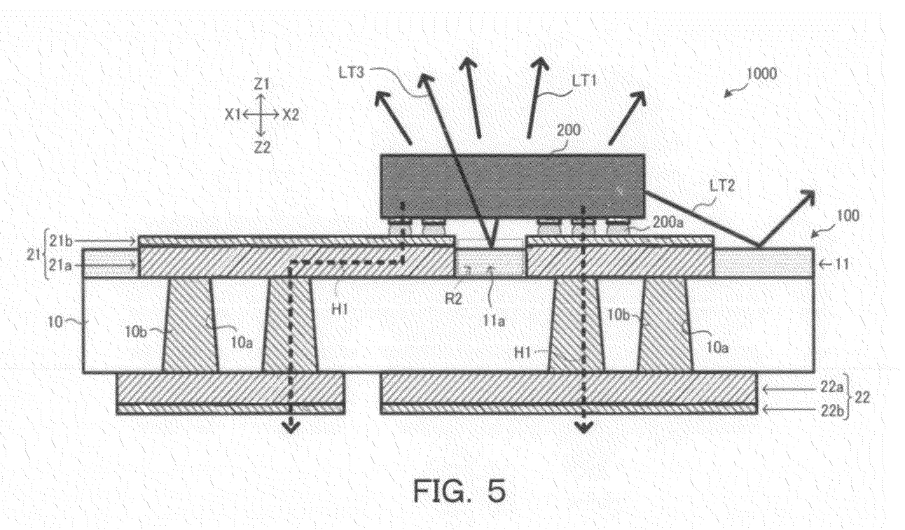

It is preferable that the thickness of the substrate 10 should be within a range from substantially 0.05 to substantially 0.5 mm. If the thickness of the substrate 10 is less than substantially 0.05 mm, the rigidity of the substrate 10 is reduced and the substrate 10 is easily deformed, which causes the white reflective film 11 formed on the surface to be easily separated. Moreover, if the thickness of the substrate 10 exceeds substantially 0.5 mm, the through-hole conductors 10b of the substrate 10 become long, which makes it difficult for the LED wiring board to obtain a heat dissipation action (see FIG. 5) to be discussed later.

According to this embodiment, the conductor layer 21 is formed on the first plane F1 of the substrate 10. The conductor layer 21 includes the conductor pattern 21a (a lower layer) and a corrosion resistant film 21b (an upper layer). The corrosion resistant film 21b is formed on a surface of the conductor pattern 21a, and protects the conductor pattern 21a.

According to this embodiment, the conductor layer 21 corresponds to a wiring pattern layer. The conductor layer 21 includes wiring patterns 21c and 21d that function as the wiring or the pad for the LED device 200. The wiring pattern 21c (a first wiring pattern) and the wiring pattern 21d (a second wiring pattern) are electrically insulated with each other, and have substantially identical thickness. As shown in FIG. 2, the wiring pattern 21c is electrically connected to the anode (or the cathode) of the LED device 200, while the wiring pattern 21d is electrically connected to the cathode (or the anode) of the LED device 200. As shown in FIG. 2, according to the light emitting module 1000 of this embodiment, the LED device 200 is mounted in a flip-chip manner. Hence, the electrodes of the LED device 200 are electrically connected to the wiring patterns 21c and 21d of the conductor layer 21 through solders 200a (see FIG. 2).

According to this embodiment, the conductor layer 22 is formed on the second plane F2 of the substrate 10. The conductor layer 22 includes the conductor pattern 22a (a lower layer) and a corrosion resistant film 22b (an upper layer). The corrosion resistant film 22b is formed on a surface of the conductor pattern 22a, and protects the conductor pattern 22a. The conductor layers 21 and 22 are electrically connected together via the through-hole conductors 10b. The conductor layer 22 includes a wiring pattern and a pad electrically connected to the LED wiring patterns of the conductor layer 21.

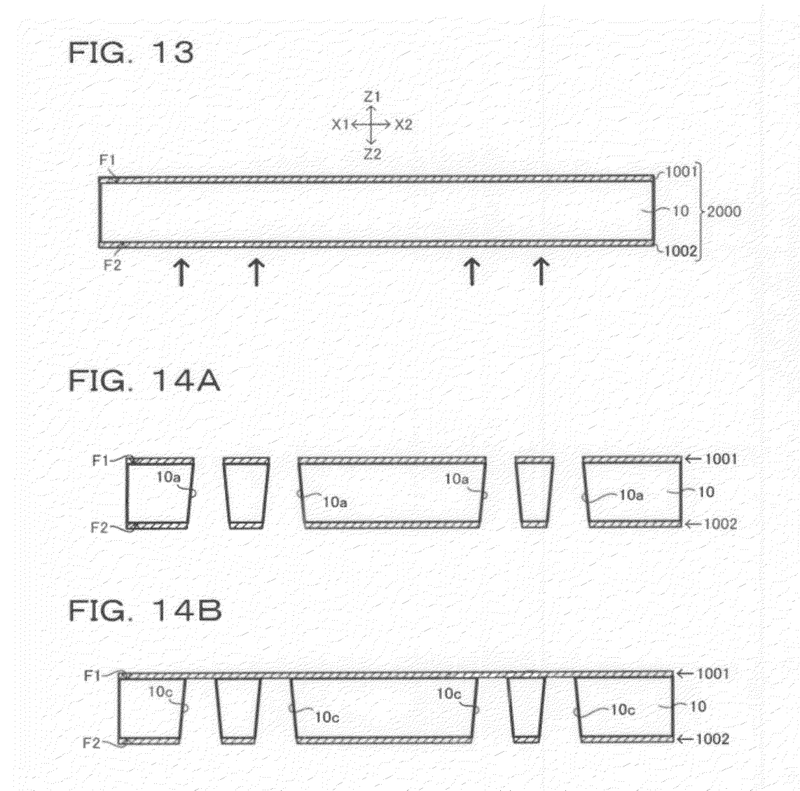

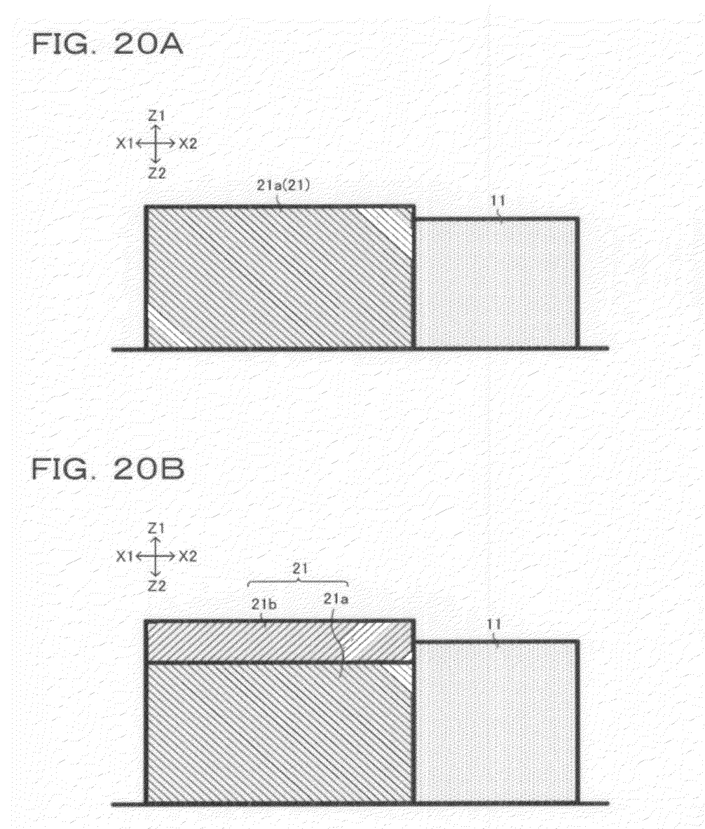

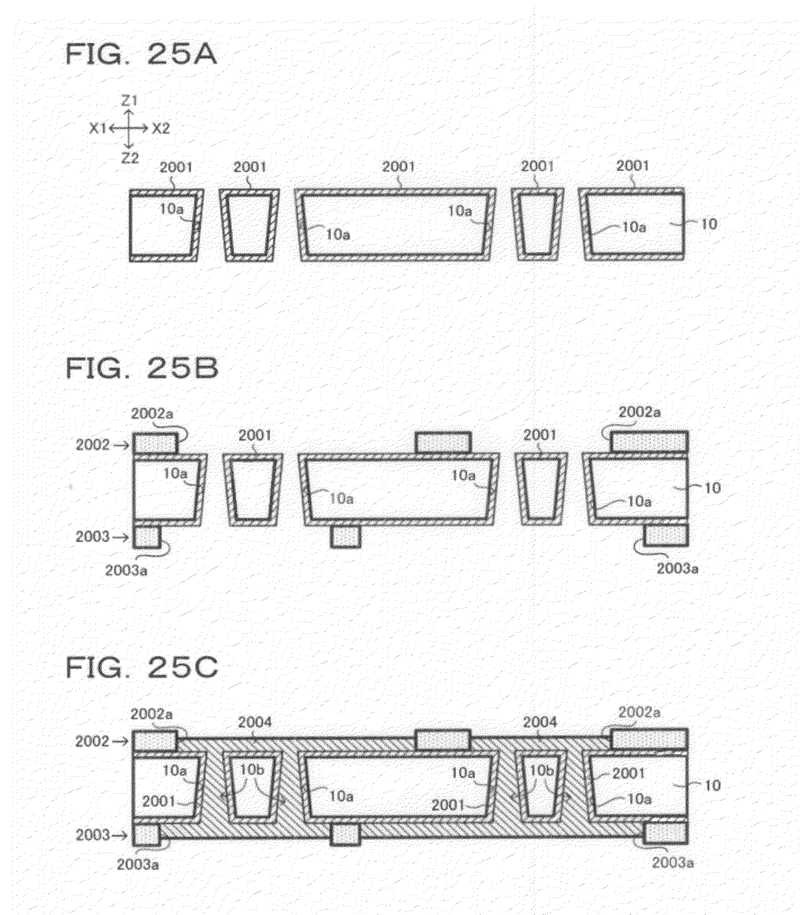

The conductor patterns 21a and 22a are each formed of a copper foil (a lower layer) and a copper plating (an upper layer) (see FIGS. 13 to 16 to be discussed later). Moreover, the corrosion resistant films 21b and 22b are each formed of, for example, an Ni/Au film. Respective corrosion resistant films 21b and 22b can be formed by electrolytic plating, non-electrolytic plating, and sputtering, etc. The present invention is not limited to such schemes, and the material and shape of the conductor layers 21 and 22 are optional. For example, the conductor patterns 21a and 22a may be each formed of a plating film only (see FIGS. 25A to 25C to be discussed later). Moreover, the corrosion resistant film 21b or 22b that is an organic protective film may be formed through an OSP (Organic Solderability Preservatives) process (including an organic protective film and processes like heat-resistant soluble pre-fluxing and pre-fluxing). Furthermore, the corrosion resistant films 21b and 22b are not essential elements, and can be omitted if unnecessary (see FIG. 20A to be discussed later).

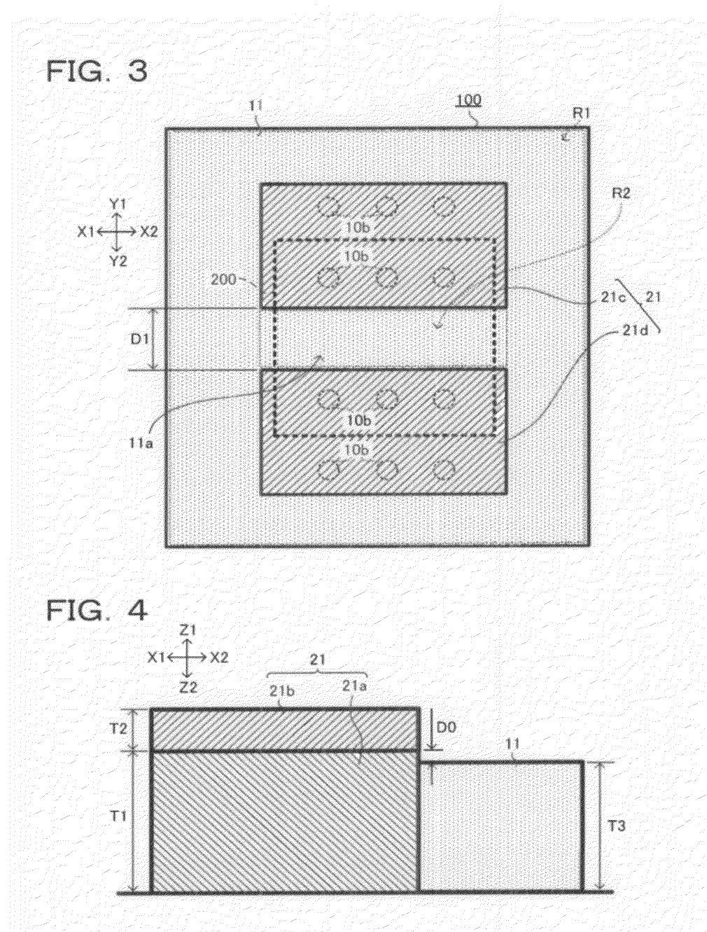

FIG. 3 shows an illustrative shape of the conductor layer 21 (the wiring pattern layer). In the example shown in FIG. 3, the rectangular wiring pattern 21d and the rectangular wiring pattern 21c are disposed with a predetermined space D1. The present invention is not limited to this configuration, and the shape of the conductor layer 21 (the wiring pattern layer) is optional (see FIG. 21 to be discussed later).

As shown in, for example, FIG. 3, the through-hole conductors 10b are intensively laid out right below the LED device 200. Such a layout facilitates the LED wiring board to obtain the heat dissipation action (see FIG. 5) to be discussed later. In order to enhance the heat dissipation action, it is preferable that the through-hole conductors 10b should be disposed across substantially whole area of the LED device 200. However, the present invention is not limited to this configuration, and the number of through-hole conductors 10b and the layout thereof are optional. The number of the through-hole conductors 10b may be one or a multiple number.

Formed on the first plane F1 of the substrate 10 are not only the conductor layer 21 (in a precise sense, the conductor part thereof) but also the white reflective film 11. That is, the white reflective film 11 is formed on non-conductor parts R1 and R2 (a space between the conductor patterns) of the conductor layer 21. The non-conductor part R2 is a non-conductive portion located between the wiring pattern 21c (the first wiring pattern) and the wiring pattern 21d (the second wiring pattern), and the non-conductor part R1 is the other non-conductive portion. According to this embodiment, the white reflective film 11 includes a white colorant and a binder thereof. It is preferable that the white colorant used should be powders. The white reflective film 11 improves a reflectance regardless of the color and material of the substrate 10. The white reflective film 11 can also function as a solder resist.

FIG. 4 is a diagram for explaining a relationship between a thickness of the white reflective film 11 and that of the conductor layer 21 in the LED wiring board 100 according to the embodiment of the present invention. As shown in FIG. 4 (the partial enlarged view of FIG. 1), according to this embodiment, the whole white reflective film 11 is thinner than the conductor layer 21 (including the wiring pattern 21c and the wiring pattern 21d). This facilitates disposing of the white reflective film 11 right below the LED device 200 and filling of an under-fill material. Moreover, the wiring pattern 21c (the first wiring pattern) and the wiring pattern 21d (the second wiring pattern) have substantially identical thickness. This facilitates mounting of the LED device 200 on the conductor layer 21 without a tilting. According to this embodiment, the whole white reflective film 11 is thinner than the conductor pattern 21a (the conductor layer other than the corrosion resistant film 21b).

Moreover, according to this embodiment, as shown in FIGS. 2 and 3, the LED device 200 is disposed on the wiring patterns 21c and 21d across the non-conductor part R2, and a part of the white reflective film 11 (hereinafter, referred to as a device-corresponding part 11a) is disposed right below the LED device 200. The device-corresponding part 11a of the white reflective film 11 is located between the wiring pattern 21c and the wiring pattern 21d.

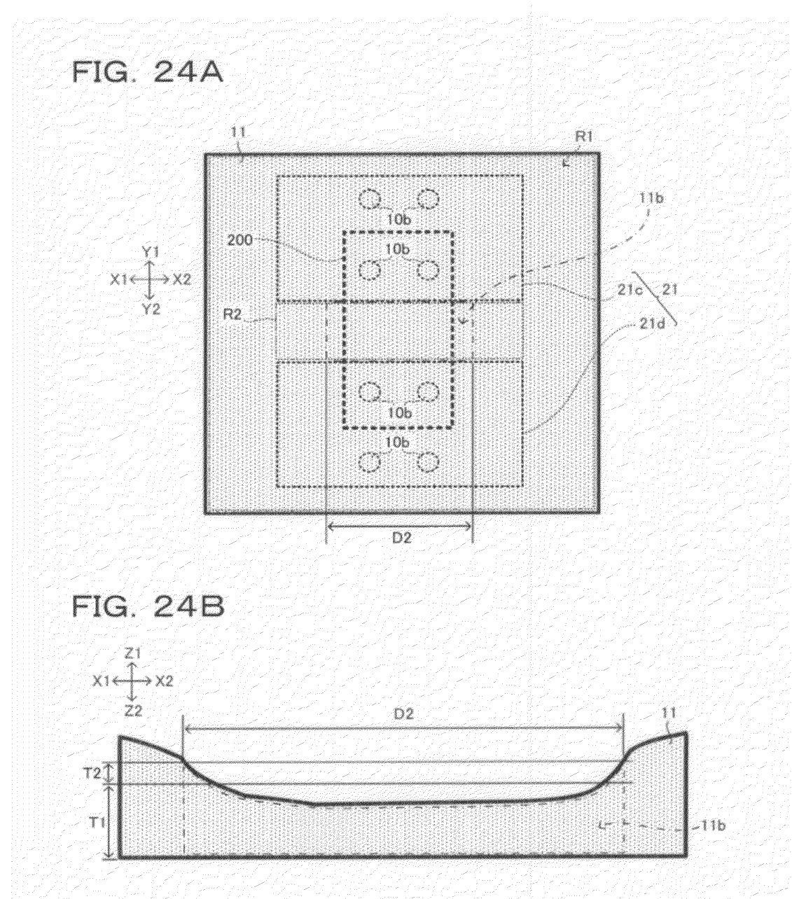

Example dimensions of the conductor pattern 21a, the corrosion resistant film 21b and the white reflective film 11 are as follows: the conductor pattern 21a has a thickness T1 of substantially 50 μm; the corrosion resistant film 21b has a thickness T2 of substantially 5 μm, and the white reflective film 11 has a thickness T3 of substantially 45 μm. According to this example, a difference D0 between the thickness T1 of the conductor pattern 21a and the thickness T3 of the white reflective film 11 is substantially 5 μm. Such a difference in level is formed by, for example, polishing (see FIGS. 18 and 19 to be discussed later). The top face of the white reflective film 11 may be other than a flat plane, and may form, for example, a recessed surface with a smooth curve (see FIG. 24B).

FIG. 5 is a diagram for explaining an operation of the light emitting module 1000 according to the embodiment of the present invention. As shown in FIG. 5, the light emitting module 1000 of this embodiment causes the LED device 200 to emit, for example, lights LT1 to LT3. An arbitrary wavelength of light (or an arbitrary kind of the LED device 200) can be employed depending on an application of the light emitting module 1000. An example light emitted by the light emitting module 1000 is white light. Such white light can be produced by, for example, combining a blue LED (the LED device 200) with a fluorescent material. More specifically, when blue light emitted by a blue LED is focused on a yellow fluorescent material, white light can be produced. The light emitting module 1000 that emits white light can be used as an illuminator (e.g., a lamp or a headlight of an automobile) or a backlight of a liquid crystal display (e.g., a large-size display or a display of a cellular phone).

Light emitted by the LED device 200 includes the light LT1 toward the upper space of the LED device 200, the light LT2 toward the side space of the LED device 200, and the light LT3 toward the right-below space of the LED device 200. According to the light emitting module 1000 of this embodiment, the lights LT2 and LT3 are reflected by the white reflective film 11. Hence, the substrate 10 is not likely to be irradiated with light from the LED device 200, which suppresses the deterioration (in particular, the deterioration of a resin) of the substrate 10 due to light. Moreover, according to this embodiment, a part (the device-corresponding part 11a) of the white reflective light 11 is disposed right below or right below and in the vicinity of the LED device 200. Hence, the light LT3 which especially will make the substrate 10 deteriorate is reflected by the device-corresponding part 11a of the white reflective film 11. Furthermore, the white reflective film 11 itself has a high reflectance, and is not likely to change the properties thereof. Accordingly, the white reflective film 11 can maintain the high reflectance even if the substrate 10 changes the properties thereof due to heat and light emitted by the LED device 200.

The lights LT2 and LT3 are reflected by the white reflective film 11, and become light directed to the same direction as that of the light LT1. Accordingly, the light emission efficiency of the light emitting module 1000 improves.

An explanation will be given of a heat dissipation action when the through-hole conductors 10b are intensively disposed right below the LED device 200 with reference to FIG. 5. According to this embodiment, the conductor layer 21 formed of copper is electrically connected to the conductor layer 22 formed of copper via the through-hole conductors 10b formed of copper. Since metals (e.g., copper) easily transfer heat, when the LED device 200 generates heat, such a heat is possibly transferred from the electrode of the LED device 200 to the conductor layer 22 via the solder 200a, the conductor layer 21, and the through-hole conductors 10b as is indicated by an arrow H1 in FIG. 5. The heat is diffused by the conductor layer 22 (in particular, the pad). This results in improvement of the heat dissipation by the LED device 200, and thus the temperature of the LED device 200 does not easily rise.

It is preferable that the white reflective film 11 should contain, as a white colorant, at least one kind of followings: titanium dioxide; zinc oxide; alumina; silicon dioxide (e.g., steatite); magnesia; yttria; acidum boricum; calcium oxide; strontium oxide; barium oxide; and zirconia. Among those materials, it is especially preferable to contain anatase titanium dioxide. Steatite means insulator ceramics with a composition of MgO—SiO₂. It is preferable that the white reflective film 11 should contain, as a binder, at least one kind of followings: a non-organic material; an organic silicon compound (e.g., a silicon resin); and an epoxy resin. Among those materials, it is especially preferable to contain a non-organic material. Moreover, it is especially preferable that the white reflective film 11 should contain, as a binder, at least one kind of followings among the non-organic materials: a water glass cured material; a low-melting-point glass; and a non-organic sol cured material (e.g., alumina sol or silica sol). When the non-organic material is used for the white reflective film 11, an aggregate with a larger grain size than that of the white colorant may be added. Example aggregates available are zircon, silica, alumina, zirconia, and mullite, etc. Addition of the aggregate causes the white reflective film 11 to increase the strength, and thus it becomes possible to suppress a cracking of the white reflective film 11 when cured, and a separation and a peeling of the white reflective film 11 after cured. This will be explained below with reference to examples, reference examples, and comparative examples.

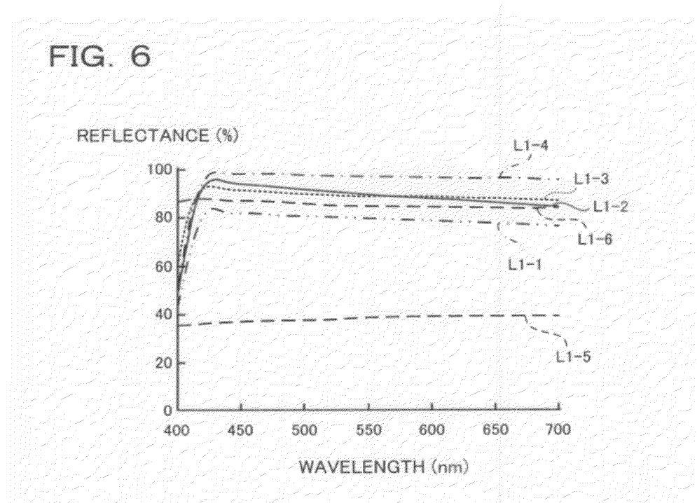

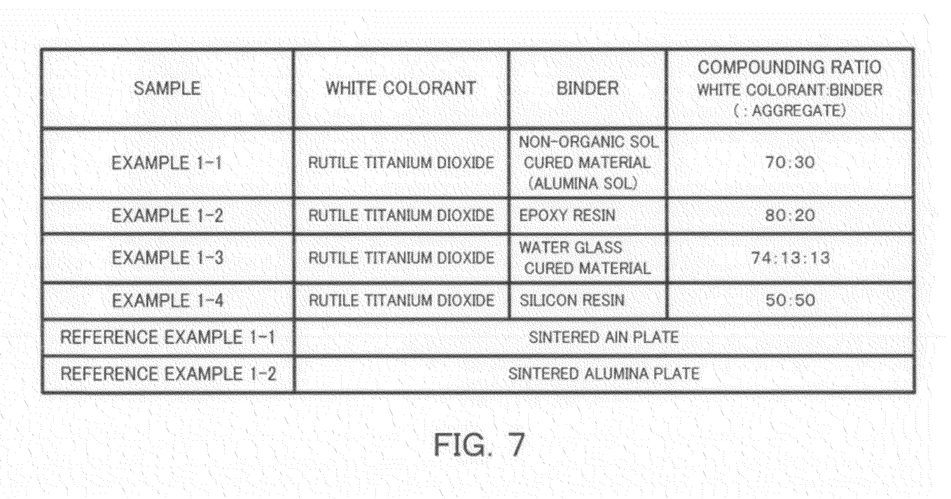

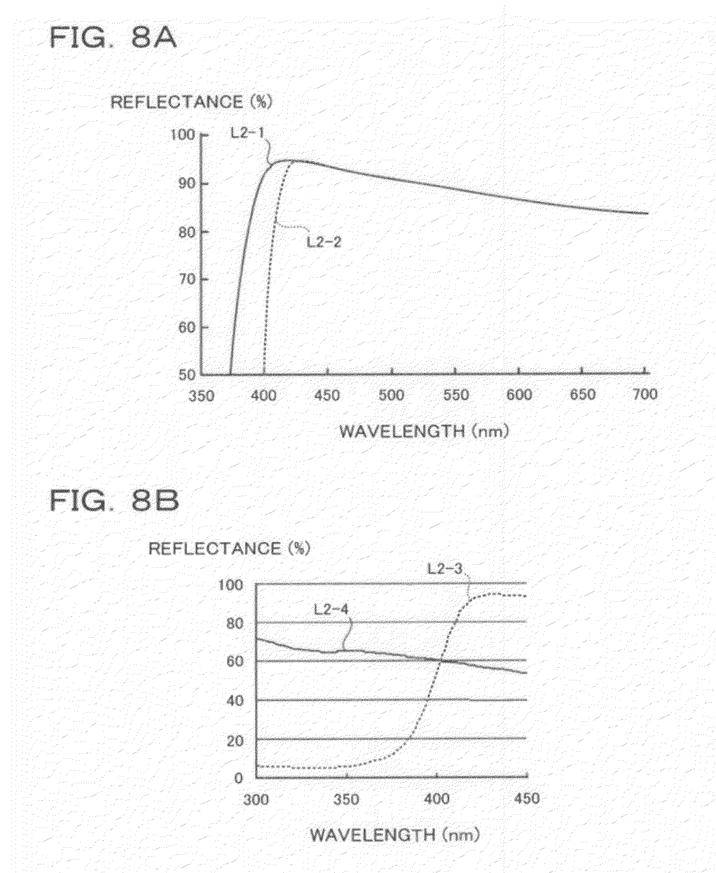

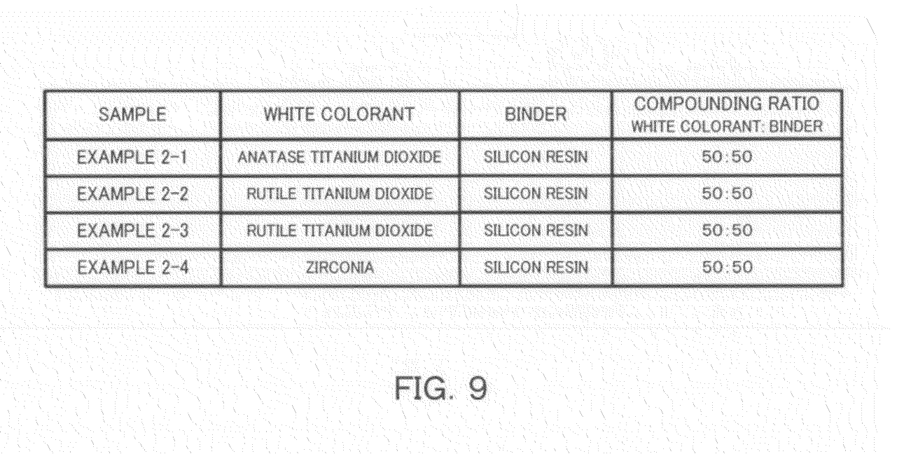

FIG. 6 is a graph showing measured results for examples 1-1 to 1-4, and reference examples 1-1 and 1-2. FIG. 7 is a table showing the detail of each sample according to the examples 1-1 to 1-4 and the reference examples 1-1 and 1-2. FIGS. 8A and 8B are graphs showing measured results for examples 2-1 to 2-4. FIG. 9 is a table showing the detail of each sample according to the examples 2-1 to 2-4.

Respective graphs of FIGS. 6, 8A and 8B show reflectance of light in a predetermined wavelength range for a material of the white reflective film 11 in the LED wiring board 100 of this embodiment. More specifically, spectroscopic reflectance in a predetermined wavelength range for respective white reflective films formed of different materials were measured through the following technique.

A material of each white reflective film was applied on a transparent glass plate of 1 mm and let cured, thereby obtaining a measurement sample with each white reflective film (examples 1-1 to 1-4, 2-1 to 2-4, and 3-1 to 3-4) having a thickness of 20 μm. The measurement samples and samples for the reference examples 1-1 to 1-2 and 3-1 and a comparative example 3-1 were subjected to reflectance measurement thereof in a wavelength of 250 to 700 nm using a spectrophotometer UV-3150 (made by SHIMADZU CORPORATION).

As shown in the graph of FIG. 6, respective reflectance of the example 1-1 (a line L1-1) in a wavelength of 430 to 700 nm other than a short wavelength range where the reflectance largely decreases, the example 1-2 (a line L1-2), the example 1-3 (a line L1-3), the example 1-4 (a line L1-4), the reference example 1-1 (a line L1-5) and the reference example 1-2 (a line L1-6) were 75 to 85%, 80 to 95%, 85 to 90%, 90 to 99%, 35 to 40%, and 80 to 90%, respectively.

In FIG. 6, lines L1-1, L1-2, L1-3, and L1-4 indicate measured results for the examples 1-1, 1-2, 1-3, and 1-4, respectively. As shown in FIG. 7, the white reflective film of the example 1-1 had the white colorant (70 pts. wt.) that was mainly composed of rutile titanium dioxide, and had the binder (30 pts. wt.) that was mainly composed of a non-organic sol (alumina sol) cured material. The white reflective film of the example 1-2 had the white colorant (80 pts. wt.) that was mainly composed of rutile titanium dioxide, and had the binder (20 pts. wt.) that was mainly composed of an epoxy resin. The white reflective film of the example 1-3 had the white colorant (74 pts. wt.) that was mainly composed of rutile titanium dioxide, had the binder (13 pts. wt.) that was mainly composed of a water glass cured material, and further contained zircon as the aggregate (13 pts. wt.). The white reflective film of the example 1-4 had the white colorant (50 pts. wt.) that was mainly composed of rutile titanium dioxide, and had the binder (50 pts. wt.) that was mainly composed of a silicon resin.

FIG. 6 also shows measured results for a sintered AlN tabular material, i.e., the reference example 1-1 (a line L1-5) and a sintered alumina tabular material, i.e., the reference example 1-2 (a line L1-6) for reference, respectively (see FIG. 7).

As shown in FIG. 6, according to the examples 1-1 to 1-4 (the lines L1-1 to L1-4), higher reflectance was obtained than the reference example 1-1 (AlN tabular material: the line L1-5), and reflectance equal to or greater than that of the reference example 1-2 (alumina tabular material: the line L1-6) was obtained. The higher reflectance was obtained by the example 1-4, the example 1-3, the example 1-2, and the example 1-1 in this order.

Based on the results shown in the graph of FIG. 6, it may be preferable that the white reflective film 11 should contain, as the white colorant, titanium dioxide or zirconia with high reflectance. According to this structure, improvement of the reflectance of the white reflective film 11 is facilitated. Moreover, when the white reflective film 11 contains, as the white colorant, at least one kind (hereinafter, referred to as a first active constituent) of followings: titanium dioxide; zinc oxide; alumina; silicon dioxide; and zirconia, substantially similar tendency may be observed. In particular, it is preferable that the white colorant of the white reflective film 11 should be mainly composed of the first active constituent. More specifically, it is preferable that equal to or greater than 50% (ratio by weight) of the white colorant composing the white reflective film 11 should be the first active constituent, and in particular, it is more preferable if equal to or greater than 80% should be the first active constituent.

Based on the results shown by the graph of FIG. 6, it seems preferable if the white reflective film 11 should contain, as the binder, an epoxy resin, a silicon resin, a water glass cured material, or a non-organic material (a non-organic adhesive) like a non-organic sol cured material. According to such a structure, improvement of the reflectance of the white reflective film 11 is facilitated due to a difference in refractive index between the white colorant and the binder. In particular, water glass containing water as a solvent causes the white colorant to be highly concentrated through a process of drying and curing even if the white colorant is applied at a low concentration. Hence, when the white reflective film 11 contains the water glass cured material as the binder, improvement of the reflectance of the white reflective film 11 can be facilitated.

When the white reflective film 11 contains, as the binder, at least one kind (hereinafter, referred to as a second active constituent) of followings: a non-organic material; an organic silicon compound; and an epoxy resin, substantially similar tendency can be observed (see the lines L1-1 to L1-4 in the graph of FIG. 6). In particular, it is preferable that the binder of the white reflective film 11 should be mainly composed of the second active constituent. More specifically, it is preferable that equal to or greater than 80% of the binder composing the white reflective film 11 should be the second active constituent, and in particular, it is more preferable if 100% of the binder should be the second active constituent.

FIG. 8A is a graph showing reflectance of light in a predetermined wavelength range (350 to 700 nm) for the white reflective film 11 containing the white colorant that was anatase titanium dioxide and for the white reflective film 11 containing the white colorant that was rutile titanium dioxide in the LED wiring board 100 according to this embodiment of the present invention.

In the graph of FIG. 8A, lines L2-1 and L2-2 indicate measured results of examples 2-1 and 2-2, respectively. As shown in FIG. 9, the white reflective film of the example 2-1 contained the white colorant (50 pts. wt.) mainly composed of anatase titanium dioxide, and contained the binder (50 pts. wt.) mainly composed of a silicon resin that was an organic silicon compound. The white reflective film of the example 2-2 contained the white colorant (50 pts. wt.) mainly composed of rutile titanium dioxide, and contained the binder (50 pts. wt.) mainly composed of a silicon resin that was an organic silicon compound.

The lowermost wavelength where the reflectance decreased to 50% was 375 nm for the example 2-1 and was 400 nm for the example 2-2.

According to the example 2-1, high reflectance was obtained at a shorter wavelength than that of the example 2-2. More specifically, it is clear that the white reflective film (the example 2-1) mainly composed of anatase titanium dioxide has higher reflectance than that of the white reflective film (the example 2-2) mainly composed of rutile titanium dioxide within a wavelength range from 375 nm to 420 nm.

Based on this result, it seems preferable that the white reflective film 11 should contain, as the white colorant, anatase titanium dioxide. According to the white reflective film 11 containing anatase titanium dioxide, when the LED device 200 of a short wavelength (in particular, a wavelength within a range from 375 to 420 nm) is used, light emitted by such an LED device can be reflected at a high rate, which facilitates suppression of a deterioration of the substrate 10 (in particular, the deterioration of the resin). It is especially preferable that the white colorant of the white reflective film 11 should be mainly composed of anatase titanium dioxide. More specifically, it is preferable that equal to or greater than 50% (ratio by weight) of the white colorant composing the white reflective film 11 should be anatase titanium dioxide, and in particular, it is more preferable that equal to or greater than 80% of the white colorant should be anatase titanium dioxide.

When anatase titanium dioxide is used, it is preferable to use the binder that is a non-organic material or an organic silicon compound. LED devices are irradiated with not only light emitted by such LED devices but also solar light containing light with a short wavelength (e.g., 315 to 400 nm) from, in particular, the exterior when used in an outdoor environment. Since anatase titanium dioxide has an intense photocatalyst action, an organic material like an epoxy resin that contains a large number of bonds, such as C—C and C—N, reacts with light emitted by the LED device or solar light, and such an epoxy resin is easily deteriorated. However, a non-organic material contains no such bonds, and an organic silicon compound contains little such bonds or no such bonds, and the binder does not easily change the properties thereof.

FIG. 8B is a graph showing reflectance of light in a predetermined wavelength range (300 to 450 nm) for the white reflective film 11 (example 2-3) formed of rutile titanium dioxide (50 pts. wt.) and a silicon resin (50 pts. wt.) and for the white reflective film 11 (example 2-4) formed of zirconia (50 pts. wt.) and a silicon resin (50 pts. wt.) in the LED wiring board 100 according to this embodiment of the present invention (see FIG. 9). Lines L2-3 and L2-4 in the graph of FIG. 8B indicate measured results for the examples 2-3 and 2-4, respectively.

As shown in FIG. 8B, according to the white reflective film (the example 2-3) containing rutile titanium dioxide, the reflectance dropped to substantially 50% at a wavelength of 400 nm, and became equal to or less than 10% at a wavelength of equal to or shorter than 350 nm. In contrast, according to the white reflective film (the example 2-4) containing zirconia, the reflectance was 60 to 70% even at wavelengths of 300 to 400 nm. Based on this result, it seems that the white reflective film of the example 2-4 does not decrease the reflectance even within an ultraviolet range. Hence, it is especially preferable to use zirconia for the white colorant of the white reflective film of an ultraviolet LED device.

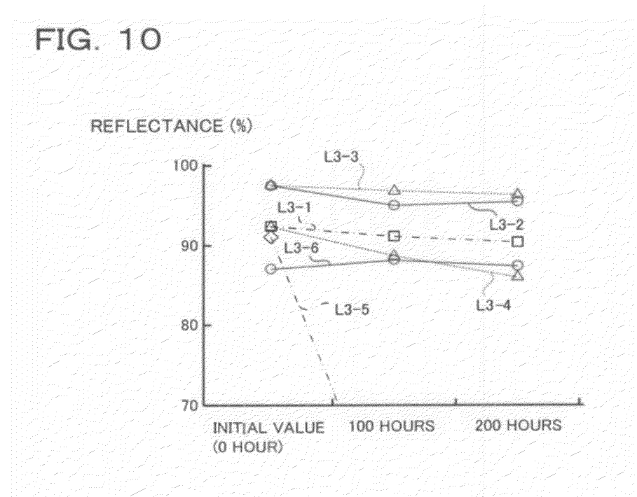

FIG. 10 is a graph showing a time-dependent change in reflectance of light with a predetermined wavelength for each white reflective film 11 formed of a different material in the LED wiring board 100 according to this embodiment of the present invention.

The graph of FIG. 10 shows a result of a breakdown test (an aging test) performed on each white reflective film 11. According to such a breakdown test, a white reflective film was processed at a temperature of 150° C., the LED device 200 was operated for a long time, and the reflectance of each white reflective film 11 was measured relative to light with a wavelength of 450 nm emitted by the LED device 200 at a predetermined timing (0 hour, 100 hours, and 200 hours). More specifically, for respective white reflective films (examples 3-1 to 3-4) formed of a different material, materials of respective white reflective films were applied on a transparent glass plate of 1 mm and let cured in order to produce measurement samples with respective white reflective films having a thickness of 20 μm. Measurement samples and plates of a reference example 3-1 and a comparative example 3-1 were processed for 0 hour, 100 hours, and 200 hours at a temperature of 150° C., and respective reflectance at those time points and at a wavelength of 450 nm were measured by a spectrophotometer UV-3150 (made by SHIMADZU CORPORATION) and were taken as measured reflectance.

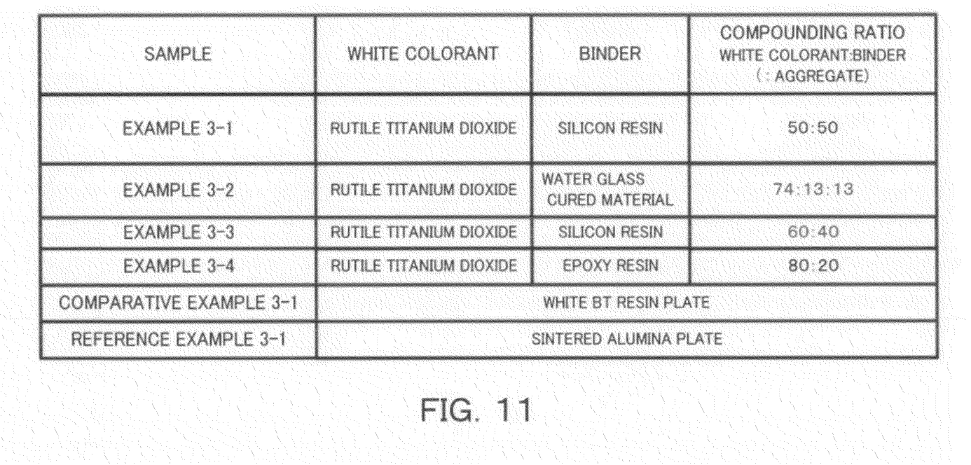

In the graph of FIG. 10, lines L3-1, L3-2, L3-3, L3-4, L3-5, and L3-6 indicate measured results for the examples 3-1, 3-2, 3-3, 3-4, the comparative example 3-1, and the reference example 3-1, respectively. FIG. 11 is a table showing the detail of each sample according to the examples 3-1 to 3-4, the comparative example 3-1, and the reference example 3-1.

As shown in FIG. 11, the white reflective film of the example 3-1 had the white colorant (50 pts. wt.) mainly composed of rutile titanium dioxide and had the binder (50 pts. wt.) mainly composed of a silicon resin. The white reflective film of the example 3-2 had the white colorant (74 pts. wt.) mainly composed of rutile titanium dioxide and had the binder (13 pts. wt.) mainly composed of a water glass cured material, and further had the aggregate (13 pts. wt.) that was zircon. The white reflective film of the example 3-3 had the white colorant (60 pts. wt.) mainly composed of rutile titanium dioxide and had the binder (40 pts. wt.) mainly composed of a silicon resin. The white reflective film of the example 3-4 had the white colorant (80 pts. wt.) mainly composed of rutile titanium dioxide and had the binder (20 pts. wt.) mainly composed of an epoxy resin.

The comparative example 3-1 was composed of a white BT resin plate (HL820W made by MITSUBISHI GAS CHEMICAL COMPANY, INC.). The white BT resin plate is a tabular material having a small amount of coloring agents added in a BT resin, and mainly composed of a BT resin. The reference example 3-1 was composed of a sintered alumina plate. According to the comparative example 3-1 and the reference example 3-1, the white BT resin plate and the sintered alumina plate reflected light instead of the white reflective film 11.

Respective reflectance of the examples, the comparative example, and the reference example after 0 hour, 100 hours, and 200 hours were as follows.

The reflectance of the example 3-1 (the line L3-1) was 90 to 93%, and no deterioration in the white reflective film was observed. The reflectance of the example 3-2 (the line L3-2) was 95 to 98%, and no deterioration in the white reflective film was observed. The reflectance of the example 3-3 (the line L3-3) was 95 to 98%, and no deterioration in the white reflective film was observed. The reflectance of the example 3-4 (the line L3-4) was 85 to 93%, and deterioration in the white reflective film was observed but was little. The reflectance of the comparative example 3-1 (the line L3-5) became equal to or smaller than 70% from 91%, and large deterioration of the white BT resin plate was observed. The reflectance of the reference example 3-1 (the line L3-6) was 85 to 89%, and no deterioration in the reflective surface was observed.

As shown in the graph of FIG. 10, respective white reflective films 11 of the examples 3-1 and 3-3 (the lines L3-1 and L3-3) using a silicon resin as the binder and the example 3-2 (the line L3-2) using the water glass cured material as the binder hardly deteriorated like the alumina plate of the reference example 3-1. The higher reflectance was obtained by the example 3-3, the example 3-2, and the example 3-1 in this order.

When the example 3-4 (the line L3-4) and the comparative example 3-1 (the line L3-5) are compared with each other, the example 3-4 which was composed of the white colorant and the binder and which used an epoxy resin and a rutile titanium dioxide as the binder and the white colorant, respectively, had little deterioration in the white reflective film in comparison with the comparative example 3-1 using the white BT resin plate.

Based on those results, it seems preferable if the white reflective film 11 should contain, as the binder, a non-organic material like a water glass cured material. According to the white reflective film 11 containing a non-organic material, the white reflective film 11 is not likely to deteriorate, and thus the durability of the LED wiring board 100 and the reliability thereof improve (see the line L3-2 in FIG. 10). This is because that a non-organic material does not likely to change the properties thereof in comparison with an organic material containing C—C bonds or C—N bonds.

Moreover, it seems preferable if the white reflective film 11 should contain, as the binder, at least one kind (hereinafter, referred to as a third active constituent) of followings: a water glass cured material; a low-melting-point glass; and a non-organic sol cured material. This is because the water glass cured material, the low-melting-point glass, and the non-organic sol cured material have high tolerability against light and heat. Furthermore, it is especially preferable if the binder of the white reflective film 11 should be mainly composed of the third active constituent. More specifically, it is preferable that equal to or greater than 80% (ratio by weight) of the binder composing the white reflective film 11 should be the third active constituent, and it is more preferable that 100% of the binder should be the third active constituent.

Conversely, among the organic materials, an organic silicon compound and an epoxy resin seem preferable as the binder. According to the white reflective film 11 containing an organic silicon compound or an epoxy resin, the white reflective film 11 is not likely to deteriorate, and thus the durability of the LED wiring board 100 and the reliability thereof improve (see lines L3-1, L3-3, and L3-4 in FIG. 10).

It is preferable if the containing amount of the white colorant in the white reflective film 11 should be 35 to 95%. When the containing amount of the white colorant is less than 35%, light easily transmits the white reflective film 11, and when the containing amount of the white colorant exceeds 95%, the binding force of the binder becomes poor, and thus the white reflective film 11 becomes brittle and cannot be easily held on the surface of the LED wiring board 100.

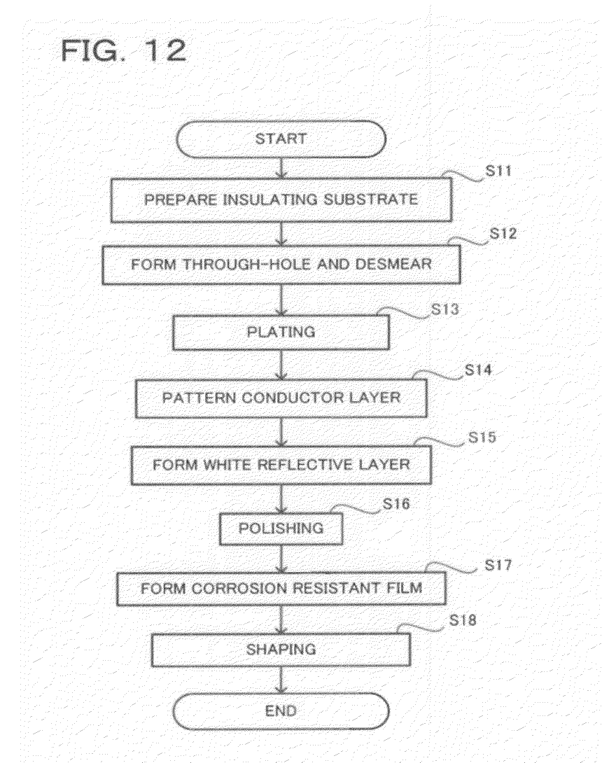

Next, an explanation will be given of a method for manufacturing the LED wiring board 100 with reference to FIG. 12, etc. FIG. 12 is a flowchart showing the outline and procedures of the manufacturing method of the LED wiring board 100 according to this embodiment. According to this embodiment, after a multiple number of LED wiring boards 100 are produced using a panel (steps S11 to S17), those LED wiring boards are cut out piece by piece (step S18).

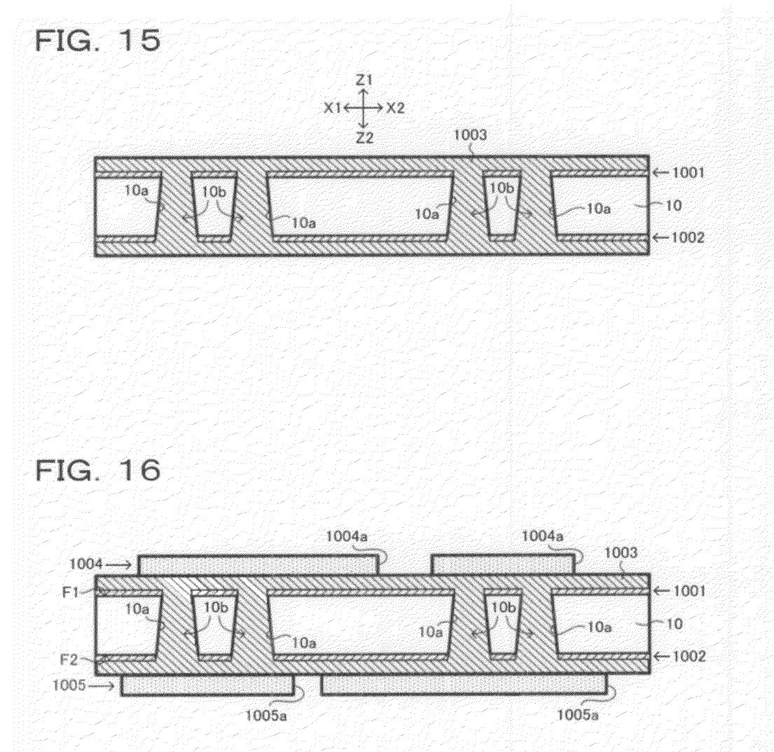

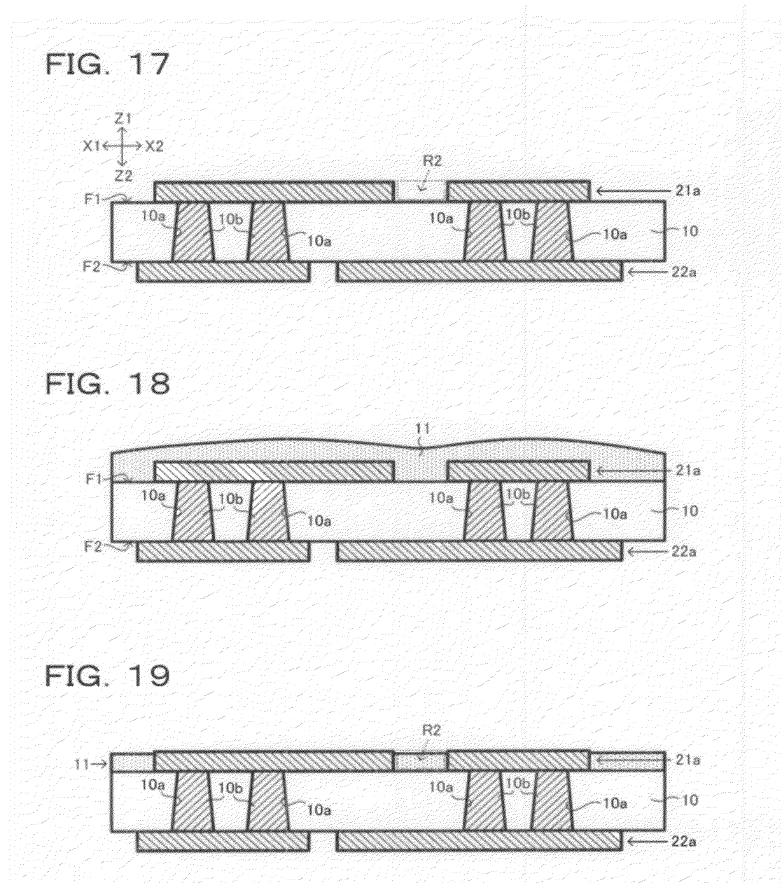

FIG. 13 is a diagram for explaining a process of preparing an insulating substrate according to the manufacturing method shown in FIG. 12. FIG. 14A is a diagram for explaining a process of forming through-holes in the insulating substrate according to the manufacturing method shown in FIG. 12. FIG. 14B is a diagram for explaining a process of forming a non-through-hole in the insulating substrate according to a modified example of the manufacturing method shown in FIG. 12. FIG. 15 is a diagram for explaining a plating process according to the manufacturing method shown in FIG. 12. FIG. 16 is a diagram for explaining a process of forming an etching resist according to the manufacturing method shown in FIG. 12. FIG. 17 is a diagram for explaining a process of etching a conductor layer according to the manufacturing method shown in FIG. 12. FIG. 18 is a diagram for explaining a first process of forming a white reflective film according to the manufacturing method shown in. FIG. 12. FIG. 19 is a diagram for explaining a second process following the first process shown in FIG. 18.

A both-surface copper-clad laminate 2000 is prepared in the step S11 as shown in FIG. 13. The both-surface copper-clad laminate 2000 includes the substrate 10, a copper foil 1001 formed on the first plane F1 of the substrate 10, and a copper foil 1002 formed on the second plane F2 of the substrate 10. According to this embodiment, the substrate 10 is composed of a glass-epoxy completely cured in this stage.

Next, in step S12 of the flowchart shown in FIG. 12, the both-surface copper-clad laminate 2000 is irradiated with laser from the second-plane-F2 side using, for example, CO₂ laser, and as shown in FIG. 14A, through-holes 10a that pass all the way through the both-surface copper-clad laminate 2000 are formed. Thereafter, desmearing is performed on each through-hole 10a. Formation of the through-hole 10a may be carried out through a scheme other than laser, such as drilling or etching. Moreover, instead of the process of forming the through-holes shown in FIG. 14A, as shown in FIG. 14B, with the copper foil 1001 on an opposite plane being left, the both-surface copper-clad laminate 2000 may be irradiated with laser to form non-through-holes 10c. In this case, the process after step S13 in FIG. 12 is identical to that of the case in which the through-holes are formed.

Next, in the step S13 shown in FIG. 12, a plating 1003 of, for example, copper is formed on the copper foils 1001 and 1002 and in the through-holes 10a as shown in FIG. 15 by, for example, panel plating. More specifically, non-electrolytic plating is performed at first, and electrolytic plating is performed using a plating solution with a non-electrolytic plate film being as a negative electrode, thereby forming the plating 1003. Accordingly, the through-holes 10a are filled with the plating 1003, and thus the through-hole conductors 10b are formed.

Next, in step S14 of the flowchart shown in FIG. 12, respective conductor layers formed on the first plane F1 and the second plane F2 of the substrate 10 are patterned.

More specifically, as shown in FIG. 16, an etching resist 1004 with an aperture 1004a and an etching resist 1005 with an aperture 1005a are formed on the principal surface (on the plating 1003) of the first plane F1 and the principal surface (the plating 1003) of the second plane F2, respectively, by lithography, etc. The apertures 1004a and 1005a respectively have patterns corresponding to the conductor layers 21 and 22 (see FIG. 1).

Next, portions of respective conductor layers (the copper foils 1001 and 1002 and the plating 1003) formed on the first plane F1 and the second plane F2 of the substrate 10 and not covered by the etching resists 1004 and 1005 (portions exposed through the apertures 1004a and 1005a) are eliminated using, for example, an etching liquid. Hence, as shown in FIG. 17, the conductor patterns 21a and 22a that can function as wirings of the LED device 200 (see FIG. 2) are formed on the first plane F1 and the second plane F2 of the substrate (an insulator layer) 10, respectively. Note that the type of etching is not limited to wet, but may be dry.

Next, in step S15 of the flowchart shown in FIG. 12, the white reflective film 11 is formed on the first plane F1 of the substrate (an insulator layer) 10 by, for example, screen printing as shown in FIG. 18. The white reflective film 11 is composed of a white colorant and a binder thereof. In this stage, the white reflective film 11 is formed so as to be thicker than the conductor pattern 21a and cover the conductor pattern 21a. When the binder that is an organic material like a silicon resin or an epoxy resin is used for the white reflective film 11, for example, a non-cured resin is mixed with the white colorant, and is printed on the first plane F1 of the substrate (the insulator layer) 10. Moreover, the non-cured resin is let cured at a temperature of 100 to 150° C. maintained for 10 to 60 minutes, thereby obtaining the white reflective film 11. When the binder that is a non-organic material is used for the white reflective film 11, the white colorant and the binder are dissolved in, for example, water (a solvent or a dispersion medium), and are printed on the first plane F1 of the substrate (the insulator layer) 10. The dissolved materials are naturally dried for, for example, 12 to 24 hours, heated and cured step by step up to 150° C. in order to volatilize the moisture, thereby obtaining the white reflective film 11. When a non-organic material is used for the white reflective film 11, a change in volume becomes large before and after drying due to the use of, for example, water. Hence, in order to suppress a cracking at the time of drying, an aggregate with a larger grain size than that of the white colorant may be added. Example aggregates available are zircon, silica, alumina, zirconia, and mullite. Addition of the aggregate increases the strength of the white reflective film 11 and suppresses a cracking at the time of drying. Moreover, the aggregate increases the strength, which suppresses separation and peeling of the white reflective film 11 after cured.

Next, in step S16 of the flowchart shown in FIG. 12, the surface of the white reflective film 11 is polished to make the white reflective film 11 thin as shown in FIG. 19. Hence, the white reflective film 11 becomes thinner than the conductor pattern 21a (see FIG. 4). An example scheme of polishing is buffing. That is, abrasive grains are applied to a buff formed of a material with a flexibility (e.g., a cotton cloth or a linen), and the buff is pushed against the white reflective film 11 while rotating the buff at a high speed, thereby scraping the surface of the white reflective film 11.

Next, in step S17 of the flowchart shown in FIG. 12, corrosion resistant films 21b and 22b (see FIG. 1) formed of, for example, an Ni/Au film are formed on the conductor patterns 21a and 22a, respectively, by electrolytic plating or sputtering, etc. Hence, the conductor layers 21 and 22 shown in FIG. 1 are formed, and the LED wiring board 100 is finished. Note that corrosion resistant films 21b and 22b formed of an organic protective film may be formed by an OSP process.

Thereafter, in step S18 of the flowchart shown in FIG. 12, shaping is performed on each LED wiring board 100 formed on a panel, thereby obtaining individual LED wiring boards 100. After an inspection, the only LED wiring boards that passed the inspection are taken as products. Moreover, the LED device 200 is mounted on the LED wiring board 100 obtained thus way, thereby producing the light emitting module 1000.

The manufacturing method of this embodiment is appropriate for manufacturing the LED wiring board 100 and the light emitting module 1000. Such a method provides good LED wiring board 100 and light emitting module 1000 at a low cost.

The present invention is not limited to the above-explained embodiment. The present invention can be changed and modified as follows.

FIG. 20A is a cross-sectional view showing an example having the corrosion resistant film 21b of the wiring pattern layer (the first wiring pattern and the second wiring pattern) omitted in the LED wiring board 100 according to the embodiment of the present invention. FIG. 20B is a diagram for explaining a modified example relating to the dimension of the white reflective film 11 in the LED wiring board 100 according to the embodiment of the present invention.

As shown in FIG. 20A, the corrosion resistant film 21b may be omitted. In this case, the conductor pattern 21a corresponds to the conductor layer 21 (the first wiring pattern and the second wiring pattern) as a wiring pattern layer.

As shown in FIG. 20B, the white reflective film 11 may be thicker than the conductor pattern 21a. When the white reflective film 11 is thinner than the conductor layer 21 (the first wiring pattern and the second wiring pattern), the white reflective film 11 can be easily disposed right below the LED device 200, or the LED device 200 can be easily mounted on the conductor layer 21 without any tilting of the LED device 200.

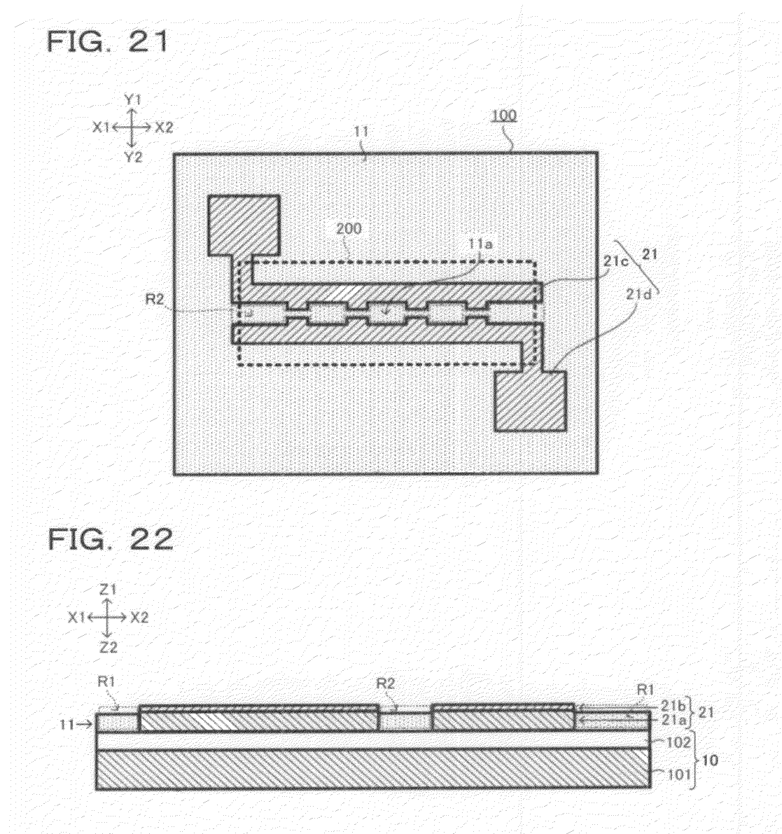

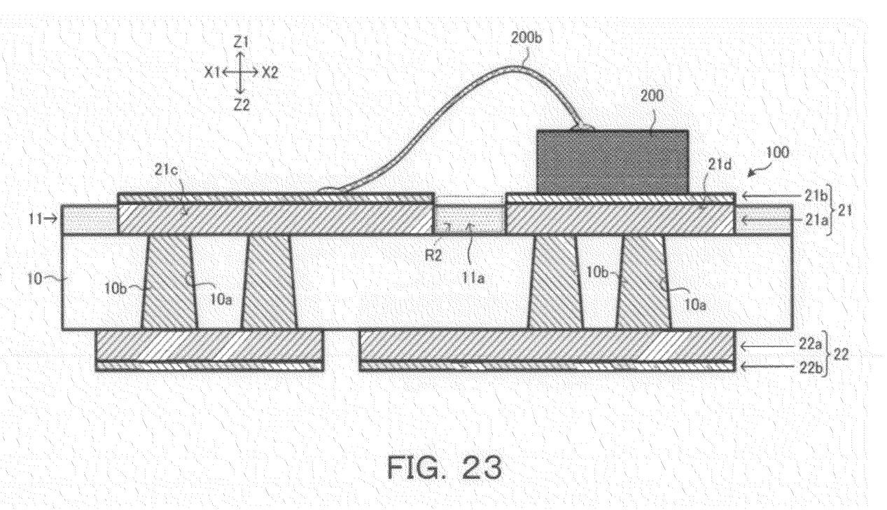

FIG. 21 is a plan view showing another shape of the wiring pattern layer (the first wiring pattern and the second wiring pattern) according to the embodiment of the present invention. FIG. 22 is a cross-sectional view showing a modified example of the insulator layer according to another embodiment of the present invention. FIG. 23 is a diagram showing another example having the LED device 200 mounted in a different scheme in the light emitting module 1000 according to the embodiment of the present invention.

The shape of the conductor layer 21 (the first wiring pattern and the second wiring pattern) is not limited to the shape shown in FIG. 3, and is optional. For example, as shown in FIG. 21, the conductor layer 21 may include bar-like (in precise, comb-like) wiring patterns 21c and 21d facing with each other.

The shape and material of the substrate 10 are basically optional. For example, the substrate 10 may include a plurality of layers formed of different materials. According to the embodiment, the substrate 10 is a rigid substrate. However, the type of the substrate 10 is not limited to the former one, and may be a flexible substrate, etc.

The substrate 10 is not limited to the insulating substrate, and for example, as shown in FIG. 22, may include a metal substrate 101 and an insulator layer 102 formed on the metal substrate 101. According to the example shown in FIG. 22, the conductor layer 21 (the first wiring pattern and the second wiring pattern) and the white reflective film 11 are formed on the insulator layer 102. Moreover, the substrate 10 may be adopted which is a ceramic substrate formed of alumina or AlN (aluminum nitride). The ceramic substrate has higher thermal conductivity and durability than those of the resin substrate.

According to the above-explained embodiment, the through-hole conductors 10b are each a filled conductor, but the through-hole conductors 10b may be each a conformal conductor. Moreover, as shown in FIG. 22, the through-hole conductors 10b may be omitted.

However, in order to enhance the heat dissipation action, it is effective to provide the through-hole conductors 10b (in particular, ones each of which is a filled conductor) (see FIG. 5).

The mounting scheme of the LED device 200 is not limited to flip-chip, and is optional. For example, as shown in FIG. 23, the LED device 200 may be mounted by wire-bonding. According to the example shown in FIG. 23, an electrode of the LED device 200 is electrically connected to the wiring pattern 21c of the conductor layer 21 via a wire 200b.

FIG. 24A is a plan view showing an LED wiring board according to the other embodiment of the present invention. FIG. 24B is a partial cross-sectional view of the LED wiring board shown in FIG. 24A. According to the above-explained embodiment, the whole white reflective film 11 is thinner than the conductor layer 21 (the first wiring pattern and the second wiring pattern). The present invention is, however, not limited to this structure, and for example, as shown in FIGS. 24A and 24B, when the white reflective film 11 has a thin part (hereinafter, referred to as a device-corresponding part 11b) from the wiring pattern 21c (the first wiring pattern) to the wiring pattern 21d (the second wiring pattern), if the LED device 200 is disposed above the device-corresponding part 11b, the LED device 200 can be mounted on the wiring patterns 21c and 21d without any interference with the white reflective film 11. It is preferable that a width D2 of the device-corresponding part 11b should be in a size that enables mounting of the LED device 200 as shown in FIG. 24A.

However, it is more preferable that the whole area (the non-conductor part R2) at least between the wiring pattern 21c (the first wiring pattern) and the wiring pattern 21d (the second wiring pattern) should be thinner than both of the wiring patterns 21c and 21d. According to such a structure, disposing of the white reflective film 11 right below the LED device 200 is surely facilitated, or the LED device 200 can be easily mounted on the conductor layer 21 without any tilting of the LED device 200.

Regarding other features, the structures of the LED wiring board 100 and the light emitting module 1000 and the kind, performance, dimension, material, shape, number of layers, or layout of such structures can be changed and modified accordingly without departing from the scope and spirit of the present invention.

For example, the LED wiring board 100 is a printed wiring board having a conductor layer (the conductor layer 21, 22) on each principal surface, but the substrate 10 which is a core substrate may be used and a multi-layer printed wiring board employing a multi-layer structure may be used.

The material of each conductor layer is not limited to the above-explained example, and can be changed depending on an application, etc. For example, a metal other than copper may be used as the material for the conductor layer. The same is true of the material of the through-hole conductor.

The manufacturing processes of the LED wiring board 100 and the light emitting module 1000 are not limited to the procedures and details shown in the flowchart of FIG. 12, and can be changed and modified as needed without departing from the scope and spirit of the present invention. Moreover, processes which are unnecessary depending on an application, etc. may be omitted.

According to the above-explained embodiment, the conductor layers 21 and 22 are formed through a subtractive technique, but how to form each conductor layer is optional. For example, the conductor layers 21 and 22 may be formed through any one of or any combination of equal to or greater than two of followings: panel plating; pattern plating; a full-additive technique; a semi-additive technique (SAP); a subtractive technique; transferring; and tenting.

FIGS. 25A to 25C show an illustrative case in which the conductor layers 21 and 22 are formed through SAP. FIG. 25A is a diagram for explaining a first process of forming a wiring pattern layer (the first wiring pattern and the second wiring pattern) according to the yet other embodiment of the present invention. FIG. 25B is a diagram for explaining a second process following the first process shown in FIG. 25A. FIG. 25C is a diagram for explaining a third process following the second process shown in FIG. 25B.

According to this example, after the through-holes 10a are formed through the same technique as that of the above-explained embodiment (see FIGS. 13 and 14), a catalyst like palladium is adsorbed on the surface of the substrate 10 by, for example, dipping. Next, as shown in FIG. 25A, a non-electrolytic plating film 2001 formed of, for example, copper is formed on the first plane F1 and the second plane F2 of the substrate 10 and the walls of the through-holes 10a by, for example, chemical plating.

Next, as shown in FIG. 25B, a plating resist 2002 with an aperture 2002a and a plating resist 2003 with an aperture 2003a are respectively formed on the principal surface (the non-electrolytic plating film 2001) of the first plane F1 and on the principal surface (the non-electrolytic plating film 2001) of the second plane F2 by lithography or printing, etc. The apertures 2002a and 2003a have respective patterns corresponding to the conductor layers 21 and 22 (see FIG. 1).

Next, as shown in FIG. 25C, pieces of electrolytic plating 2004 formed of, for example, copper are formed in the apertures 2002a and 2003a of the plating resists 2002 and 2003 by, for example, pattern plating. More specifically, copper that is a material to be plated is connected to a positive electrode, and the non-electrolytic plating film 2001 subjected to plating is connected to a negative electrode and both are dipped in a plating solution. A DC voltage is applied across both electrodes to let a current flow, thereby depositing copper on the surface of the non-electrolytic plating film 2001. Hence, the through-holes 10a are filled with the electrolytic plating 2004, and thus the through-hole conductors 10b are formed.

Thereafter, the plating resists 2002 and 2003 are eliminated using, for example, a predetermined repellent, and the unnecessary portions of the non-electrolytic plating film 2001 are successively eliminated, thereby forming the conductor layers 21 and 22 (see FIG. 17).

The seed layer for electrolytic plating is not limited to a non-electrolytic plating film, and a sputter film, etc. may be used as the seed layer instead of the non-electrolytic plating film 2001.

The above-explained embodiment and the modified examples can be combined accordingly. It is preferable to select an appropriate combination depending on an application, etc. For example, the structure shown in FIG. 20A or 20B may be applied to the structure shown in any of FIGS. 21 to 24A.

Although the explanation was given of the embodiment of the present invention, it should be understood that various modification and combination to be necessary for design matter and other factors are included in the invention set forth in “claims” and the scope and spirit of the invention corresponding to the specific disclosure by the “detailed description”.

Having described and illustrated the principles of this application by reference to one or more preferred embodiments, it should be apparent that the preferred embodiments may be modified in arrangement and detail without departing from the principles disclosed herein and that it is intended that the application be construed as including all such modifications and variations insofar as they come within the spirit and scope of the subject matter disclosed herein.

What is claimed is:

1. An LED wiring board comprising:
an insulator layer;
a wiring pattern layer formed on the insulator layer; and
a white reflective film which is formed on the insulator layer and which comprises a white colorant and a binder thereof,
the wiring pattern layer comprising a first wiring pattern and a second wiring pattern, and
the white reflective film including a portion which is between the first wiring pattern and the second wiring pattern and which is thinner than both of the first wiring pattern and the second wiring pattern.

2. The LED wiring board according to claim 1, wherein the white reflective film contains, as the white colorant, at least one of followings: titanium dioxide; zinc oxide; alumina; silicon dioxide; magnesia; yttria; acidum boricum; calcium oxide; strontium oxide; barium oxide; and zirconia.

3. The LED wiring board according to claim 2, wherein the titanium dioxide is an anatase-type.

4. The LED wiring board according to claim 1, wherein the white reflective film contains, as the binder, at least one of followings: a non-organic material; an organic silicon compound; and an epoxy resin.

5. The LED wiring board according to claim 4, wherein the white reflective film contains, as the binder, a non-organic material.

6. The LED wiring board according to claim 5, wherein the non-organic material is at least one of followings: water glass cured material; a low-melting-point glass; and a non-organic sol cured material.

7. The LED wiring board according to claim 1, wherein the insulator layer is a resin substrate.

8. The LED wiring board according to claim 7, wherein the resin substrate comprises a primary material that is a thermosetting resin and a reinforcement material.

9. The LED wiring board according to claim 8, wherein the reinforcement material has a smaller thermal expansion coefficient than a thermal expansion coefficient of the primary material.

10. A light emitting module comprising:
the LED wiring board according to claim 1; and
an LED device.

11. A method for manufacturing an LED wiring board, comprising:
forming a wiring pattern and a white reflective film on an insulator layer, the white reflective film comprising a white colorant and a binder thereof; and
polishing a surface of the white reflective film to make the white reflective film thinner than the wiring pattern.

12. The method according to claim 11, wherein the white reflective film contains, as the white colorant, at least one of followings: titanium dioxide; zinc oxide; alumina; silicon dioxide; magnesia; yttria; acidum boricum; calcium oxide; strontium oxide; barium oxide; and zirconia.

13. The method according to claim 12, wherein the titanium dioxide is an anatase-type.

14. The method according to claim 12, wherein the white reflective film contains, as the binder, at least one of followings: a non-organic material; an organic silicon compound; and an epoxy resin.

15. The method according to claim 14, wherein the white reflective film contains, as the binder, a non-organic material.

16. The method according to claim 15, wherein the non-organic material is at least one of followings: water glass cured material; a low-melting-point glass; and a non-organic sol cured material.

17. The method according to claim 11, wherein the insulator layer is a resin substrate.

18. The method according to claim 17, wherein the resin substrate comprises a primary material that is a thermosetting resin and a reinforcement material.

19. The method according to claim 18, wherein the reinforcement material has a smaller thermal expansion coefficient than a thermal expansion coefficient of the primary material.

20. A method for manufacturing a light emitting module, comprising mounting an LED device on the LED wiring board manufactured by the method according to claim 11.
